(19) United States
(12) Patent Application Publication
(10) Pub. No.: US 2016/0306092 A1
(43) Pub. Date: Oct. 20, 2016

(54) PLANAR ILLUMINATION DEVICE

(71) Applicant: MINEBEA CO., LTD., Kitasaku-gun (JP)

(72) Inventor: Takahito YOSHIDA, Fukuroi-shi (JP)

(73) Assignee: MINEBEA CO., LTD., Kitasaku-gun (JP)

(21) Appl. No.: 15/094,597

(22) Filed: Apr. 8, 2016

(30) Foreign Application Priority Data
Apr. 15, 2015 (JP) 2015-083360

(51) Int. Cl. F21V 8/00; H05K 1/18; H05K 1/03; H05K 1/02

(52) U.S. Cl. CPC G02B 6/009; G02B 6/0031; H05K 1/0274; H05K 1/181; H05K 1/0393; H05K 1/0313; H05K 2201/0141; H05K 2201/10106

(57) ABSTRACT

A planar illumination device includes: a point light source; a flexible printed circuit board on which the point light source is mounted; and a light guide plate including an edge surface being arranged facing the point light source and a light emitting surface planarly emitting light having entered from the edge surface. The flexible printed circuit board includes a base film and a wiring layer formed on the base film, and includes, on a side on which the point light source is mounted, a first region extending in a belt shape including a part directly under the point light source, and a second region extending in a belt-shape being adjacent to a front side of the first region and the part directly under the point light source in the first region and the second region are devoid of a coverlay film.

### CROSS-REFERENCE TO RELATED APPLICATION(S)

The present application claims priority to and incorporates by reference the entire contents of Japanese Patent Application No. 2015-083360 filed in Japan on Apr. 15, 2015.

### BACKGROUND OF THE INVENTION

1. Field of the Invention

The present invention relates to a side-lighting planar illumination device.

2. Description of the Related Art

As an illumination unit of a liquid crystal display panel or other devices, conventionally, there has been known a side-lighting planar illumination device (backlight) in which light sources are disposed along a side edge surface of a light guide plate. In particular, a planar illumination device including a light-emitting diode (LED) as a light source, which is small and has an excellent environmental adaptability, is widely used mainly in the field of small mobile information devices such as mobile phones. Recent disclosures propose a technique related to an LED used in such a planar illumination device, by which electrode terminals of the LED are structured without providing the electrode terminals with parts arranged on a mount surface of an LED body (refer to Japanese Patent Laid-open No. 2014-107307, for example).

The LEDs having the electrode terminal structures as disclosed in Japanese Patent Laid-open No. 2014-107307 are effective in a height reduction of the LEDs and thus a thickness reduction of a planar illumination device including the height-reduced LEDs. However, when such LEDs are mounted on a conventional circuit board (typically, a flexible printed circuit board including a coverlay film partly disposed between a pair of electrode terminals of the LED as illustrated in FIG. 6), the lifting of the electrode terminals of the LEDs off lands on the circuit board may lead to an electrical and/or mechanical connection failure. Accordingly, a conventional planner illumination device has the problem that a reduction of the thickness thereof by the use of such LEDs as a light source is difficult.

### SUMMARY OF THE INVENTION

It is an object of the present invention to at least partially solve the problems in the conventional technology.

A planar illumination device includes: a point light source; a flexible printed circuit board on which the point light source is mounted; and a light guide plate including an edge surface being arranged facing the point light source and a light emitting surface planarly emitting light having entered from the edge surface. The flexible printed circuit board includes a base film and a wiring layer formed on the base film, and includes, on a side on which the point light source is mounted, a first region extending in a belt shape including a part directly under the point light source, and a second region extending in a belt-shape being adjacent to a front side of the first region and the part directly under the point light source in the first region and the second region are devoid of a coverlay film.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a side view of a main part of a planar illumination device according to one embodiment of the present invention;

FIG. 2 is a plan view of a main part of an FPC in the planar illumination device illustrated in FIG. 1 when viewed from a surface on which an LED is mounted;

FIG. 3 is a plan view of lands of the FPC in the planar illumination device illustrated in FIG. 1 and an LED mounted on the lands;

FIG. 4 is a sectional side view of an example of the planar illumination device according to the embodiment of the present invention, which includes an FPC including a blue-light reflecting unit;

FIG. 5 is a side view of a main part of another example of the planar illumination device according to the embodiment of the present invention; and

FIG. 6 is a plan view of an exemplary conventional FPC to which the lands according to the present invention is applied.

### DETAILED DESCRIPTION OF THE PREFERRED EMBODIMENTS

The following describes a planar illumination device according to an embodiment of the present invention with reference to the accompanied drawings. It is noted that, in each diagram illustrated below, the shape and the dimension of each component are illustrated, by exaggerating as appropriate in order to facilitate the understanding of the present invention.

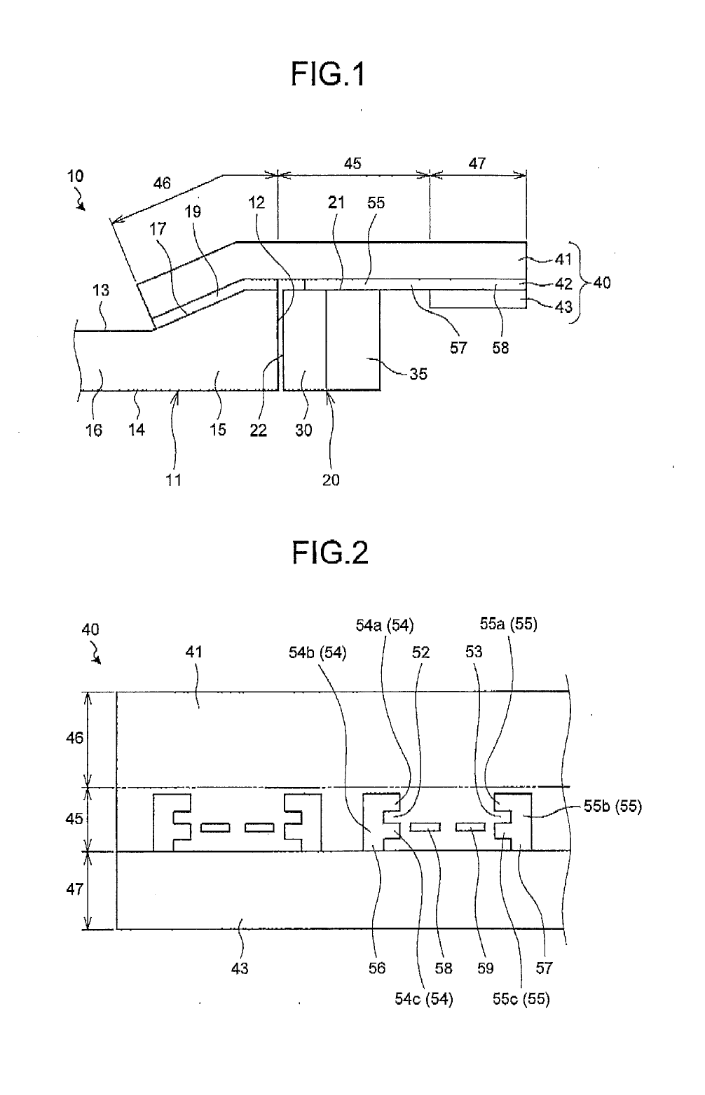

As illustrated in FIG. 1, a planar illumination device 10 includes a light guide plate 11, a plurality of point light sources 20, and a belt-shaped flexible printed circuit board (hereinafter also referred to as an FPC) 40 as a circuit board on which the point light sources 20 are mounted. In the present invention, the number of the point light sources is not limited to more than one. The number of the point light source may be one.

In the present embodiment, the point light source 20 is a pseudo white LED including a blue LED chip and a fluorescent member that are not illustrated (e.g., a yellow fluorescent member) (hereinafter, the point light source 20 is also referred to as the LED 20 in accordance with a configuration in the present embodiment). The LED 20 is so-called side-view LED including a light emitting surface 22 on one surface out of their exterior surface, the one surface being substantially orthogonal to a mount surface 21 of the FPC 40.

The light guide plate 11 is made of a transparent material (e.g. polycarbonate resin) and is formed in a rectangular shape in a top view. The exterior surface of the light guide plate 11 includes a light entering surface 12 that is an edge surface, the light entering surface 12 facing the illumination surface 22 of the LED 20. The light guide plate 11 includes a light emitting part 16, and a light receiving wedge part 15 to be described later, and the light emitting part 16 includes a light emitting surface 13 that is one of the main planes substantially orthogonal to the light entering surface 12. A back surface 14 of the light guide plate 11 is the other main plane substantially orthogonal to the light entering surface 12 and is substantially parallel to and is opposed to the light emitting surface 13.

In the present invention, a direction from the light entering surface 12 of the light guide plate 11 toward an edge surface (not illustrated) that is opposed to the light entering surface 12 is defined as an “front direction”. The front direction according to this definition is a direction in which the illumination surface 22 of the LED 20 is oriented, and happens to be the light guiding direction. Further, the direction from the back surface 14 of the light guide plate 11 toward the light emitting surface 13 is defined as an “upper direction”. The direction orthogonal to the front-rear direction and the upper-lower direction is also referred to as a left-right direction (a “right direction” and a “left direction” are defined with respect to the front direction as necessary). The left-right direction according to this definition is the longitudinal direction of the light entering surface 12, and is the direction orthogonal to the sheet of FIG. 1. However, as for a region on the FPC 40, irrespective of disposition of the FPC 40 on the light guide plate 11, the region facing the mounting surface of the LEDs 20 is referred to as the part “directly under” the LEDs 20.

In the planar illumination device 10, the light guide plate 11 includes, between the light entering surface 12 and the light emitting part 16, the light receiving wedge part 15 having a thickness gradually decreasing along the front direction (in other words, the direction from the light entering surface 12 toward the light emitting part 16). In the light receiving wedge part 15, a tilted surface 17 that is tilted to be closer to the back surface 14 as going further to the front is provided on the light emitting surface 13 side along the longitudinal direction of the light entering surface 12. The light emitting part 16 is formed in a rectangular flat plate form having a constant thickness.

With the above-described configuration, the planar illumination device 10 planarly emits, from the light emitting surface 13, as illumination light, light being emitted from the illumination surface 22 of the LEDs 20 and having entered the light guide plate 11 through the light entering surface 12. Although not illustrated, in the planar illumination device 10, a reflection sheet may be arranged on the back surface 14 side of the light guide plate 11 so as to return light leaking through the back surface 14 back into the light guide plate 11 again, and/or a diffusion sheet and a prism sheet may be arranged on the light emitting surface 13 side of the light emitting part 14 so as to control the directionality of light emitted from the light emitting surface 13. The planar illumination device 10 may include a frame member that integrally retains each component.

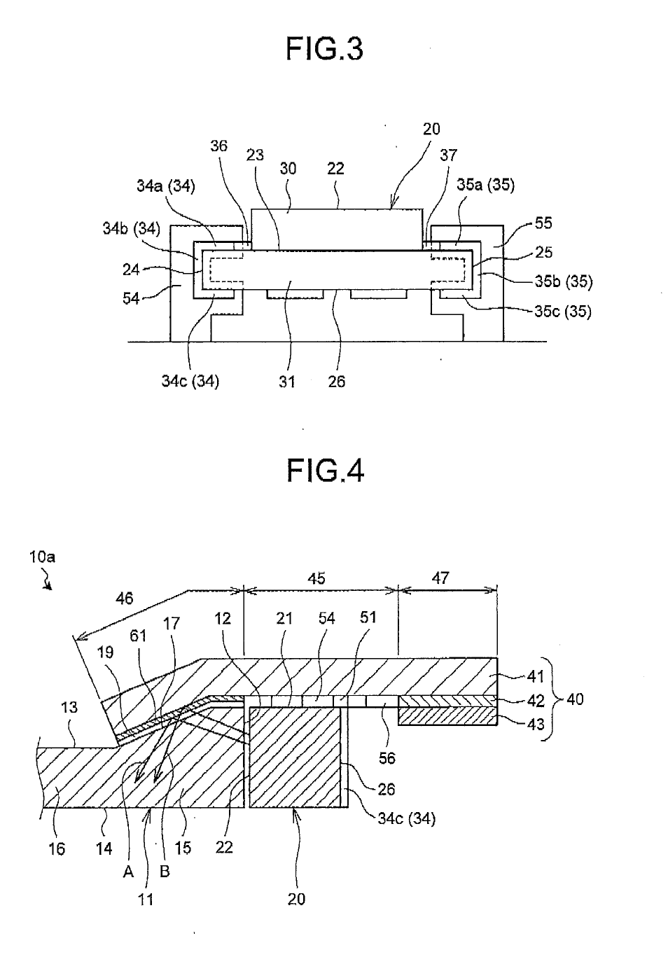

Next follows a further detailed description of the configuration of the LED 20 with reference to FIG. 3 in addition to FIG. 1. The LED 20 includes a light emitting part 30 including the blue LED chip, and a substrate 31 on the central part of which the light emitting part 30 is mounted. A pair of electrode terminals 34 and 35 are provided on the outer circumferential surface of the substrate 31 substantially orthogonal to the mount surface 21. The electrode terminal 34 is formed in a C shape (or U shape) with two corners being substantially right angles in a top view, including a front arm 34a arranged on a front surface 23 of the substrate 31, a coupling part 34b arranged on a lateral surface 24 of the substrate 31, and a rear arm 34c arranged on a rear surface 26. A mounting terminal (not illustrated) for one of the poles of the blue LED chip is provided on the front surface 23 of the substrate 31 in the light emitting part 30. The front arm 34a is connected to the mounting terminal via a drawer part 36.

Similarly, the electrode terminal 35 is formed in a C shape with two corners being substantially right angles (or U shape) in a top view, including a front arm 35a arranged on the front surface 23 of the substrate 31, a coupling part 35b arranged on a lateral surface 25 that is being opposed to the lateral surface 24, and a rear arm 35c arranged on the rear surface 26. A mounting terminal (not illustrated) for the other pole of the blue LED chip is provided on the front surface 23 of the base part 31 in the light emitting part 30, and the front arm part 35a is connected to the mounting terminal via a drawer part 37.

As described above, the electrode terminals 34 and 35 of the LED 20 are a pair of C-shaped parts whose openings are arranged facing each other in a top view. In the LEDs 20, the electrode terminals 34 and 35 have no parts arranged on the mount surface 21 side of the LED 20. Surfaces of the light emitting part 30, the substrate 31, and the electrode terminals 34 and 35, which are opposite to the FPC 40 when mounted, are formed substantially on an identical plane, and serve as the mount surface 21 of the LEO 20 as a whole.

Next follows a detailed description of the configuration of the FPC 40 with reference to FIGS. 2 and 3 in addition to FIG. 1. The FPC 40 includes a base film 41, a wiring layer 42 formed on the base film 41, and a coverlay film 43 laminated on at least part of the wiring layer 42. In the planar illumination device 10, the base film 41 is a white film. An example of a preferable material for forming the base film 41 includes a white liquid crystal polymer. However, the white film according to the present invention is not limited thereto, and may be a white member (white ink) formed (applied) on a film made of, for example, polyimide. The white member may also have a function of bonding the film and a copper foil. In addition, the base film 41 is not limited to the white film, and may be a single colored film made of, for example, polyimide depending on the required specifications. The wiring layer 42 is made of a copper foil on which various conduction patterns to be described later are formed by, for example, etching. The coverlay film 43 is formed of, for example, polyimide, but may be formed of a material having, for example, a function of a bonding member.

The conduction patterns formed on the wiring layer 42 include lands 54 and 55 (refer to FIG. 2) connected with the electrode terminals 34 and 35 of the LED 20. The planar illumination device 10 includes a plurality of the LEDs 20 arrayed along the longitudinal direction of the light entering surface 12 of the light guide plate 11. A plurality of pairs of the lands 54 and 55 to each pair of which a corresponding pair of the electrode terminals 34 and 35 of the LEDs 20 are connected are linearly arrayed on a side of the FPC 40, on which the LEDs 20 are mounted. The FPC 40 includes, on the side on which the LEDs 20 are mounted, an extended belt-shaped first region 45 including the parts directly under the LEDs 20, and the pairs of the lands 54 and 55 are all included in the first region 45. A direction in which the belt-shaped first region 45 extends is the longitudinal direction of the light entering surface 12 when the FPC 40 on which the LEDs 20 are mounted is disposed relative to the light guide plate 11

The FPC 40 further includes, on the side on which the LEDs 20 are mounted, a belt-shaped second region 46 adjacently provided in front of the first region 45 (typically, in front of the position corresponding to the light emitting surfaces 22 of the LEDs 20) and extending in the same direction as that in which the first region 45 extends, and a belt-shaped third region 47 adjacently provided on the back of the first region 45 and extending in the same direction as that in which the first region 45 extends. The FPC 40 includes the coverlay film 43 neither in the first region 45 nor in the second region 46 but only in the third region 47.

The FPC 40 does not include the wiring layer 42 in the second region 46. Specifically, the conduction patterns of the wiring layer 42 formed on the side of the FPC 40, on which the LEDs 20 are mounted, include conduction patterns 58 formed in the third region 47, the lands 54 and 55, and connection lines 56 and 57 for connecting the lands 54 and 55 with the conduction patterns 58 (refer to FIG. 1) in the third region 47. In this configuration, the connection lines 56 and 57 connect the lands 54 and 55 with the conduction patterns 58 without passing through the second region 46.

In other words, in the FPC 40, the second region 46 in front of the first region 45 includes the base film 41 only, the first region 45 includes the base film 41 and the wiring layer 42 formed on the base film 41, and the third region 47 on the back of the first region 45 includes the base film 41, the wiring layer 42 formed on the base film 41, and the coverlay film 43 laminated on the wiring layer 42.

In the planar illumination device 10, the lengths of the belt-shaped first region 45 and the second region 46 in the left-right direction (the longitudinal direction of the light entering surface 12 of the light guide plate 11) are preferably substantially the same as the length of the light entering surface 12 of the light guide plate 11 in the longitudinal direction. Typically, the length of the FPC 40 in the left-right direction is substantially the same as the length of the light entering surface 12 in the longitudinal direction, and the belt-shaped first region 45 and the belt-shaped second region 46 continuously extend over the entire length of the FPC 40 in the left-right direction.

As illustrated in FIG. 2, each of the pair of the lands 54 and 55 corresponding to a pair of the electrode terminals 34 and 35 of each LED 20 includes openings 52 and 53, which are a pair of C-shaped parts (or U-shaped parts) arranged facing each other. Specifically, the land 54 includes a front arm 54a, a coupling part 54b, and a rear arm 54c. The land 54 is formed in such a C shape with two corners being substantially right angles (or U shape) that the corresponding ends of the front arm 54a and the rear arm 54c extending in substantially parallel to each other are coupled through the coupling part 54b extending in a direction substantially orthogonal to the front arm 54a and the rear arm 54c.

Similarly, the land 55 includes a front arm 55a, a coupling part 55b, and a rear arm 55c, and is formed in such a C shape with two corners being substantially right angles (or U shape) that the corresponding ends of the front arm 55a and the rear arm 55c extending substantially parallel to each other are coupled through the coupling part 55b extending in a direction substantially orthogonal to the front arm 54a and the rear arm 54c. The pair of the lands 54 and 55 are arranged such that the other ends of the front arm 54a and the rear arm 54c of the land 54, which are not coupled through the coupling part 54b, are opposite to the other respective ends of the front arm 55a and the rear arm 55c of the land 55, which are not coupled through the coupling part 55b (in other words, the openings 52 and 53 face each other). In other words, the pair of the lands 54 and 55 includes rectangular notches extending from sides thereof, which are opposite to each other, toward the respective opposite sides.

As illustrated in FIG. 3, when the LEDs 20 is mounted on the FPC 40, the electrode terminal 34 as one of the paired electrode terminals of the LEDs 20 is connected with the land 54 as the corresponding one of the paired lands, whereas the electrode terminal 35 as the other electrode is connected with the land 55 as the other land. The pair of the lands 54 and 55 are formed such that, when the LEDs 20 is mounted, the front arm 34a, the coupling part 34b, and the rear arm 34c of the electrode 34 correspond to the front arm 54a, the coupling part 54b, and the rear arm 54c of the land 54, respectively, whereas the front arm 35a, the coupling part 35b, and the rear arm 35c of the electrode 35 correspond to the front arm 55a, the coupling part 55b, and the rear arm 55c of the land 55, respectively. Moreover, the pair of the lands 54 and 55 are formed such that, when the LEDs 20 is mounted thereon, the C-shaped outlines of the pair of the electrode terminals 34 and 35 of the LEDs 20 in a top view are included in the C-shaped outlines of the corresponding pair of the lands 54 and 55 while the correspondence relation described above is maintained. Moreover, the pair of the lands 54 and 55 are formed such that the pair of the electrode terminals 34 and 35 of the LEDs 20 are each positioned closer to three sides defining the inner outline (notch) (not three sides defining the outer outline) of the corresponding one of the pair of the lands 54 and 55.

Belt-shaped patterns 58 and 59 (refer to FIG. 2) provided inside the pair of the lands 54 and 55 facing each other are markers for examining the mount position of the LED 20. The mount-position examining markers 58 and 59 are formed to indicate the position of the rear surface 26 of the LED 20 when the LED 20 is mounted on the FPC 40 at a correct position with a correct orientation (refer to FIG. 3). In the planar illumination device 10, the mount-position examining markers 58 and 59 are formed on, for example, the wiring layer 42 similarly to the lands 54 and 55.

In the planar illumination device 10, the FPC 4Q on which the LEDs 20 are mounted is arranged relative to the light guide plate 11 by fixing the second region 46 on the light emitting surface 13 side of the light guide plate 11. Accordingly, the LEDs 20 mounted on the FPC 40 are each arranged along the longitudinal direction of the light entering surface 12 in such a manner that the light emitting surfaces 22 are opposite to the light entering surface 12 of the light guide plate 11.

In the planar illumination device 10, the second region 46 of the FPC 40 is fixed on the light receiving wedge part 15 of the light guide plate 11, specifically, on the tilted surface 17 provided on the light emitting surface 13 side of the light receiving wedge part 15 (including a flat surface illustrated in FIG. 1 as necessary). The second region 46 of the FPC 40 is bonded on the tilted surface 17 through a bonding member 19 such as a two-sided adhesive tape. In the planar illumination device 10, the specific configuration and disposition of the bonding member 19 may be an optional configuration appropriate for mechanical and optical characteristics required for the planar illumination device 10.

The FPC 40 included in the planar illumination device 10 is what is called a single-sided board. In other words, the wiring layer 42 and the coverlay film 43 are laminated only on one side of the base film 41 in the FPC 40. However, the FPC included in the planar illumination device according to the present invention may be what is called a two-sided board or a multi-layer board. In this case, the FPC according to the present invention needs to include no coverlay film 43 in the first and second regions 45 and 46 provided on the side on which the LED 20 is mounted. In the planar illumination device according to the present invention, when an FPC that is a two-sided board or a multi-layer board includes a surface on which the LED 20 is not mounted, whether a coverlay film is provided on this surface can be determined as appropriate and as necessary, and in a case in which the coverlay film is provided thereon, the disposition of the coverlay film can be determined as appropriate and as necessary.

Similarly, when the FPC is a two-sided board or a multi-layer board including no conduction pattern in the second region 46, the FPC may have, as necessary, an appropriate disposition of conduction patterns in a part of the surface of the FPC, on which the LED 20 is not mounted, and a part inside a multi-layer structure, the parts corresponding to the second region 46. When a two-sided board or a multi-layer board is used as a circuit board, a blind via hole that electrically connects the lands with a wiring layer other than the wiring layer 42 may be provided on the lands so as to achieve an improved delamination resistance of the lands in the first region.

Nest follows a description of effects of the planar illumination device 10 configured as described above. In the planar illumination device 10, the FPC 40 includes, on its side on which the LED 20 is mounted, the extended belt-shaped first region 45 including the part directly under the LED 20, and does not include the coverlay film 43 in the first region 45. This configuration allows the planar illumination device 10 including an LED such as the LED 20 having this electrode terminal structure to achieve an electrically and mechanically reliable connection between each of the electrode terminals 34 and 35 and the corresponding one of the lands.

The above-described electrode terminal structure is such a structure that the electrode terminals 34 and 35 are devoid of parts arranged on the mount surface 21 of the LED 20. The surfaces of the body (the light emitting part 30 and the substrate 31) of the LED 20 and the electrode terminals 34 and 35, which are opposite to the FPC 40 when mounted, are formed substantially on an identical plane. In general, when the LED 20 having such a configuration is mounted on the FPC, for example, if the coverlay film 43 is arranged directly under at least part of the mount surface 21 of the LED 20 corresponding to the substrate 31 to which the electrode terminals 34 and 35, the mount surface 21 (electrode terminals 34 and 35) is lifted off the wiring layer 43 by the thickness of the coverlay film 43. This may potentially generate a mechanical and/or electrical connection failure between each of the electrode terminals 34 and 35 of the LED 20 and the corresponding one of the lands 54 and 55.

In the planar illumination device 10 configured as described above, however, when the LED 20 is mounted on the FPC 40, the entire mount surface 21 of the LED 20 (including the surfaces of the electrode terminals 34 and 35) is arranged on the wiring layer 42 without the coverlay film 43 therebetween, thereby achieving the above-described effects.

The LED 20 having the electrode terminal structure described above can reduce the LED height. Accordingly, the planar illumination device 10 can achieve a reduction in a mount height including the thickness of the FPC 40 when the LED 20 is mounted on the FPC 40, exploiting this characteristic of the LED 20 having the above-described configuration. This configuration facilitates a thickness reduction of the planar illumination device 10.

The region with which no coverlay film 43 is provided in the planar illumination device 10 is provided as the extended belt-shaped first region 45, instead of being provided as openings in part of the coverlay film 43, which correspond to the pair of the lands 54 and 55, (for example, when the LEDs 20 are included, for each of the lands 54 and 55 corresponding to each LED 20). The FPC 40 has no coverlay film 43 in, as well as the first region 45, the extended belt-shaped second region 46 (continuously) provided adjacently in front of the first region 45. This configuration can facilitate a more effective thickness reduction of the planar illumination device especially when the FPC 40 is disposed such that at least part of the first region 45 and/or the second region 46 is placed over the light guide plate 11. For example, when the LEDs 20 are disposed at a relatively large pitch, a plurality of branches extending to some extent in the front direction from the front side of the coverlay film 43 arranged in the third region 47 may be provided. Each of the branches may be disposed in at least part of a space between the adjacent LEDs 20. In other words, the effects are provided at a certain level as long as the coverlay film 43 is not in at least the part directly under the LED 20 (opposite to the mount surface 21) in the first region 45.

Accordingly, the planar illumination device 10, in which the second region 46 of the FPC 40 is fixed on the light emitting surface 13 side of the light guide plate 11, facilitates a more effective thickness reduction. In particular, the planar illumination device 10 includes the light receiving wedge part 15 having a thickness gradually decreasing along the front direction between the light entering surface 12 and the light emitting part 16 of the light guide plate 11, and the second region 46 is fixed to the light receiving wedge part 15. Thus, the planar illumination device 10 can achieve a more effective thickness reduction of the part corresponding to the light emitting part 16 of the light guide plate 11.

In the planar illumination device 10, the second region 46 of the FPC 40 is fixed on the tilted surface 17 of the light receiving wedge part 15. However, the planar illumination device according to the present invention may further provide the light receiving wedge part 15 with a base seat to which the FPC 40 is fixed, and the second region 46 may be fixed to the base seat.

The planar illumination device according to the present invention achieves the effects independently of whether the coverlay film 43 is provided on the back of the first region 45 of the FPC 40. Thus, the FPC according to the present invention may additionally be devoid of coverlay film 43 in a region on the back of the first region 45.

However, in the planar illumination device 10, the FPC 40 includes the coverlay film 43 in the extended belt-shaped third region 47 adjacently provided on the back of the first region 45, thereby achieving an improved mechanical strength of the FPC 40 without reducing the reliability of connection between each of the electrode terminals 34 and 35 of the LED 20 and the corresponding one of the lands 54 and 55 or encumbering a thickness reduction of the planar illumination device 10.

In the planar illumination device 10, the FPC 40 includes the coverlay film 43 in the third region 47 and does not have the wiring layer 42 in the second region 46. In other words, the conduction pattern 58 necessary for the FPC 40 is all formed in the third region 47 except for conduction patterns needed to be formed in the second region 46, such as the lands 54 and 55 and the connection lines 56 and 57. This configuration can minimize the provision of conduction pattern not protected by the coverlay film 43, without reducing the reliability of connection between each of the electrode terminals 34 and 35 of the LEDs 20 and the corresponding one of the lands 54 and 55 or encumbering a thickness reduction of the planar illumination device 10. In other words, the planar illumination device 10 can provide the other conduction patterns with sufficient protection (including lift-off prevention and oxidation prevention) by the coverlay film 43.

In the planar illumination device 10, the FPC 40 includes a white film, which achieves the following effects.

A base film of a conventional FPC is typically a colored film of, for example, polyimide, and has an orange color when made of polyimide. In general, illumination light emitted from the light guide plate 11 includes light emitted through a path that provides reflection by the base film 41 in the first region 45 and/or the second region 46 after emitted from the LEDs 20. This configuration may potentially generate color unevenness due to the color of the base film included in the illumination light emitted from the light guide plate 11.

The planar illumination device 10, however, achieves a reduced generation of such color unevenness because the base film 41 is a white film. The base film 41, which is a white film, achieves an improved reflectance as compared to a case in which the base film 41 is colored, thereby achieving an improved luminance of the illumination light.

In the planar illumination device 10, the lands 54 and 55, to which the electrode terminals 34 and 35 of the LEDs 20 are connected, include a pair of C-shaped parts arranged such that the openings 52 and 53 face each other. In addition, in the planar illumination device 10, as described above with reference to FIG. 3, the electrode terminals 34 and 35 of the LED 20 include a pair of C-shaped parts arranged such that their openings face each other in a top view. The pair of the lands 54 and 55 are formed such that, when the LED 20 is mounted thereon, the C-shaped parts of the electrode terminals 34 and 35 (for example, the front arm 34a, the coupling part 34b, and the rear arm 34c) correspond to the C-shaped parts of the lands 54 and 55 (for example, the front arm 54a, the coupling part 54b, and the rear arm 54c) in a top view, respectively, and the C-shaped outlines of the pair of the electrode terminals 34 and 35 of the LED 20 are included in the C-shaped outlines of the pair of the respective lands 54 and 55 in a top view.

The above-described configuration of the planar illumination device 10 allows a self alignment to be effectively performed in the two axial directions of the front-back direction and the left-right direction when the electrode terminals 34 and 35 of the LED 2Q are connected with the lands 54 and 55 through the reflow process of a soldering material. This configuration achieves an accurate and reliable mount of the LED 20 onto the FPC 40.

This method of connecting the electrode terminals 34 and 35 of the LED 20 with the land 54 through the reflow process of the soldering material is preferable because of the advantage described above. In the planar illumination device 10, however, the electrode terminals 34 and 35 of the LED 20 and the lands 54 and 55 may be connected through any other connecting member such as a conductive adhesive agent.

In the planar illumination device 10, the electrode terminals 34 and 35 of the LED 20 are formed in C shapes with two corners being substantially right angles and the lands 54 and 55 are formed in C shapes with two corners being substantially right angles in a top view. In the planar illumination device according to the present invention, however, the lands 54 and 55 only need to include a pair of C-shaped parts (rectangular notches) arranged such that the openings 51 and 52 face each other. In this case, when the electrode terminals 34 and 35 include C-shapes parts in a top view and these parts are arranged in C-shaped parts of the lands 54 and 55 with the above-described configuration, the self alignment effect described above is achieved. For example, rectangular openings in a top view may be formed in regions facing each other (in other words, the rectangular openings may be formed such that sides of the rectangular notches of the lands 54 and 55, which face each other, are closed) such that the pair of the lands 54 and 55 are included in sides corresponding to the C-shaped parts (three parts) of the electrode terminals 34 and 35 of the LEDs 20 in a top view.

Next follows a description of another exemplary planar illumination device according to one embodiment of the present invention with reference to FIG. 4. Note that a planar illumination device 10a illustrated in FIG. 4 has the same configuration as that of the planar illumination device 10 illustrated in FIGS. 1 to 3 except that the FPC 40 includes a blue-light reflecting unit 61, and achieves the same effects. Thus, in the following, any duplicate description is omitted as appropriate, and a configuration and effects unique to the planar illumination device 10a are mainly described.

FIG. 4 is a sectional side view of the planar illumination device 10 taken along a line passing through the center of any one of the LEDs 20 in the left-right direction. As illustrated in FIG. 4, in the planar illumination device 10a, the FPC 40 includes the blue-light reflecting unit 61 in at least part of the second region 46. The blue-light reflecting unit 61 is a reflecting member having a relatively larger reflectance for light emitted from the blue LED chip of the LED 20 than a reflectance for light of other colors. The light of other colors includes colored light in a range from green light to red light including light such as yellow light having a wavelength longer than that of blue light. The blue-light reflecting unit 61 is formed by adhering or applying a blue member having such a reflection characteristic on a certain position of the second region 46. For example, the blue member is blue ink or a blue film, the blue-light reflecting unit 61 is formed by the application of the blue ink or the adhesion of the blue film.

The planar illumination device 10a achieves the following effects due to the blue-light reflecting unit 61 included in the second region 46 of the FPC 40, in addition to the effects described above for the planar illumination device 10.

In general, a planar illumination device may have the problem of yellowing in illumination light due to various factors. In contrast, in the planar illumination device 10a, which includes the blue-light reflecting unit 61 in the FPC 40, a blue light component is a main component in light emitted from the light guide plate 11 after having been reflected by the blue-light reflecting unit 61. This configuration can suppress the yellowing of the illumination light emitted from the light guide plate 11, thereby achieving an improved quality of the illumination light.

In particular, in a planar illumination device such as the planar illumination device 10a including the light guide plate 11 having the light receiving wedge part 15, light emitted from the vicinity of a boundary between the light receiving wedge part 15 and the light emitting part 16 of the light guide plate 11 generally produces relatively strong yellowing that can be visualized as color unevenness. Thus, the planar illumination device 10a including the blue-light reflecting unit 61 in the second region 46 of the FPC 40 particularly fixed on the light receiving wedge part 15 can reduce such color unevenness, thereby achieving improved uniformity of the color tone of the illumination light.

The base film 41 of the FPC 40 in the planar illumination device 10a is a white film. Accordingly, blue light emitted from the light guide plate 11 through the blue-light reflecting unit 61 can include not only light reflected by the blue-light reflecting unit 61 (for example, light passing an optical path illustrated by arrow A in FIG. 4), but also light reflected by the base film 41 after having been transmitted through the blue-light reflecting unit 61 (for example, light passing an optical path illustrated by arrow B in FIG. 4). In contrast, in a case of a colored base film in the conventional FPC, most of the blue light transmitted through the blue-light reflecting unit 61 is absorbed by the base film, and thus does not contribute the luminance of the illumination light. Thus, the planar illumination device 10a in which the base film 41 of the FPC 40 is a white film can effectively suppress yellowing in illumination light as compared to the case of the colored base film. This effect is significant especially when a large light quantity is transmitted to the base film 41 due to a factor such as a thin thickness of the blue-light reflecting unit 61.

In the planar illumination device 10a, the disposition of the blue-light reflecting unit 61 in the second region 46 of the FPC 40 may be an optional disposition appropriate to have a space in the second region 46 for the bonding member 19 in accordance with the disposition and mechanical and optical characteristics required for the planar illumination device 10a.

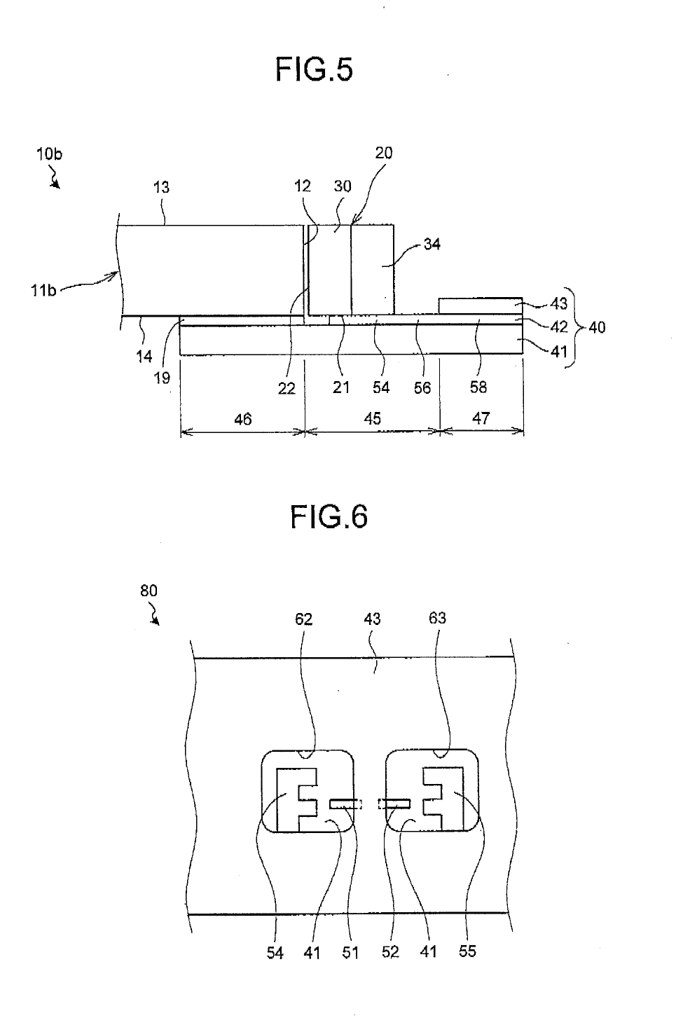

In the planar illumination device according to the present invention, the FPC 40 may be fixed on the back surface 14 side of the light guide plate 11 as in a planar illumination device 10b illustrated in FIG. 5. The planar illumination device 10b provides the same effects as those of the planar illumination device 10. The planar illumination device 10b may be provided with the same light receiving wedge part as the light receiving wedge part 15. In either case, the tilted surface 17 of the light receiving wedge part 15 may be provided on one or both of the light emitting surface 13 side and the back surface 14 side.

Among the above-described characteristics of the planar illumination device 10, the shapes of the lands 54 and 55 are applicable to an FPC having an optional configuration, depending on the electrode terminal structure of an LED to be mounted. For example, the lands 54 and 55 are applicable to a conventional FPC 80 as illustrated in FIG. 6, depending on the electrode terminal structure of an LED to be mounted. In the FPC 80, the coverlay film 43 basically covers the entire conduction pattern (base film) except for openings 62 and 63 that individually or integrally expose the vicinities of the pair of the lands 54 and 55. This configuration can achieve an accurate and reliable mount by self alignment when a pair of the electrode terminals of an LED to be mounted includes C-shaped parts in a top view.

The present invention provides a planar illumination device that has the above-described configuration and can achieve a reliable electric connection between a light source and a circuit board while facilitating a thickness reduction.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A planar illumination device comprising:
a point light source;
a flexible printed circuit board on which the point light source is mounted; and
a light guide plate including an edge surface being arranged facing the point light source and a light emitting surface planarly emitting light having entered from the edge surface, wherein
the flexible printed circuit board includes a base film and a wiring layer formed on the base film, and includes, on a side on which the point light source is mounted, a first region extending in a belt shape including a part directly under the point light source, and a second region extending in a belt-shape being adjacent to a front side of the first region, and
the part directly under the point light source in the first region and the second region are devoid of a coverlay film.

2. The planar illumination device according to claim 1, wherein:
the light guide plate includes a light emitting surface substantially orthogonal to the edge surface, and a back surface being substantially parallelly opposed to the light emitting surface, and
the flexible printed circuit board is arranged relative to the light guide plate by the second region being fixed on a light emitting surface side or a back surface side of the light guide plate.

3. The planar illumination device according to claim 1, wherein:
the flexible printed circuit board includes, on the side on which the point light source is mounted, a third region extending in a belt-shape being adjacent to a back side of the first region, and
the third region includes a coverlay film.

4. The planar illumination device according to claim 1, wherein a base film of the flexible printed circuit board is a white film.

5. The planar illumination device according to claim 4, wherein the white film is made of white liquid crystal polymer.

6. The planar illumination device according to claim 1, wherein the land includes a pair of C-shaped parts with openings being arranged facing each other.

7. The planar illumination device according to claim 1, wherein the flexible printed circuit board includes a blue-light reflecting unit in the second region.
